(19) United States
(12) Patent Application Publication
(10) Pub. No.: US 2010/0088057 A1
(43) Pub. Date: Apr. 8, 2010

(54) Method for detection of a physical variable by way of a circuit breaker

(76) Inventors: Peter KOPACZEWSKI, Berlin (DE); Aron-Ernest MUSIOL, Mahlow (Waldblick) (DE)

Correspondence Address: HARNESS, DICKEY & PIERCE, P.L.C., P.O.BOX 8910, RESTON, VA, 20195, US

(21) Appl. No.: 12/588,156

(22) Filed: Oct. 6, 2009

(30) Foreign Application Priority Data
Oct. 7, 2008 (DE) 10 2008 050 753.9

(51) Int. Cl. G06F 19/00; G01R 35/00

(52) U.S. Cl. 702/104

(57) ABSTRACT

A sensor and a signal preprocessing unit for this sensor are connected in series in a circuit breaker. The series circuit is normally calibrated. According to at least one embodiment of the invention, the sensor is now calibrated individually, and the calibration value obtained during this process is used from then on. The signal preprocessing unit is also calibrated individually, and a calibration value obtained in this process is used individually. The two calibration values, possibly a plurality of calibration values, are used in order to obtain an overall calibration value, possibly a plurality of overall calibration values, and one such overall calibration value is used by a data processing unit which is connected downstream from the signal preprocessing unit. This allows considerably more exact detection of values of the physical variable.

### PRIORITY STATEMENT

The present application hereby claims priority under 35 U.S.C. §119 on German patent application number DE 10 2008 050 753.9 filed Oct. 7, 2008, the entire contents of which are hereby incorporated herein by reference.

### FIELD

At least one embodiment of the invention generally relates to a method for detection of a physical variable by way of a circuit breaker (or in a circuit breaker).

### BACKGROUND

In addition to an actual sensor, which emits signals as a function of a physical variable such as this, a signal preprocessing unit is used in a circuit breaker, and is connected downstream from the sensor. The signal preprocessing unit preprocesses the signals emitted from the sensor such that they can be used by a data processing unit. The present actual value of the physical variable is then deduced in the data processing unit on the basis of the preprocessed signals received from the signal preprocessing unit. The data processing unit normally also has the task of evaluation of a value such as this and, possibly, of emission of control signals to other units.

The performance of such units depends on the accuracy with which the physical variable is known. One example of the physical variable is the current level in a circuit breaker. The sensor is then a current sensor, for example a Rogowski transducer, and electronic components (not on a microchip) are connected downstream therefrom. The data processing unit typically comprises a microprocessor.

A circuit-breaker manufacturer normally assembles these components, which are provided by suppliers. In particular, the circuit-breaker manufacturer normally also provides the respective sensor for the physical variable.

The supplier measures the sensor, in the form of calibration. As is known, calibration means that the sensor is tested in known conditions, that is to say that predetermined values are set or have been set for the physical variable and are determined with the aid of an already calibrated sensor, and that the signals from the sensor are detected as a function of the predetermined values. A relationship can then be established between the signals from the sensor and the predetermined values. The signals from the sensor have nominal behavior. In particular, the calibration process relates to determination of any discrepancy from a nominal behavior such as this. For example, the discrepancy may comprise a simple offset or may be linearly dependent on the measurement variable, that is to say it can be indicated by way of a proportionality factor, which is typically around the value “1”.

The sensor manufacturer classifies different sensors in different tolerance classes, with the classification resulting from the determined calibration value. A sensor purchaser knows the tolerance class. The information about the precise calibration value is not passed to the sensor purchaser.

A circuit-breaker manufacturer can to a certain extent currently determine the performance of a unit for detection of a physical variable by choice of a suitable sensor. The circuit-breaker manufacturer currently likewise carries out a calibration: The sensor is coupled to the signal preprocessing unit mentioned above and, in this case as well, predetermined values are once again set for the physical variable, or are determined using another sensor. The output signals from the signal preprocessing unit are then detected as a function of the predetermined values of the physical variable, in order to allow a relationship to be derived. The so-called calibration path therefore comprises the sensor and the signal preprocessing unit, together.

When trying to detect physical variables by way of circuit breakers as exactly as possible, it has until now been necessary to obtain sensors of as high a quality as possible and to design the signal preprocessing unit as optimally as possible. The effort involved is therefore very high.

### SUMMARY

In at least one embodiment of the invention, a way is indicated in which the accuracy of detection of physical variables by circuit breakers, or in circuit breakers, can be increased with as little effort as possible.

In at least one embodiment, the sensor described initially, the signal preprocessing unit as described initially, and the data processing unit as described initially are therefore provided. With regard to the sensor, at least one first calibration value is detected, specifically relating to (pre) determined values of the physical variable the signals emitted from the sensor are detected, and one or more such first calibration values are determined therefrom, with a calibration value being recorded, in that it is used to describe a relationship between the predetermined values and the signals. The value of an offset can be quoted as a calibration value, or a proportionality factor by which the physical variable must be multiplied in order to obtain the respective signal emitted from the sensor or with the aid of which, conversely, the physical variable can be deduced from the signal emitted from the sensor.

A plurality of first calibration values can be provided when the relationships are relatively complex: A complete calibration curve can then be recorded. The signal preprocessing unit is calibrated individually in precisely the same way in at least one embodiment of the invention: Signals emitted from the signal preprocessing unit are measured with respect to (pre) determined signals which are supplied thereto, in which case a sensor may be simulated or a sensor with a known behavior is used, and the sensor is subjected to specific values of the physical variable, which are set.

At least one second calibration value is determined for the signal preprocessing unit in at least one embodiment. This is used to describe a relationship between the predetermined signals, which are supplied to the signal preprocessing unit, and the preprocessed signals emitted from it. This second calibration value may also indicate an offset, may be a proportionality factor, or a plurality of such second calibration values may be provided, which define a calibration curve.

Once at least one first calibration value relating to the sensor and at least one second calibration value relating to the signal preprocessing unit are available, at least one overall calibration value is derived from these calibration values, according to at least one embodiment of the invention. The overall calibration value then describes the relationship between values of the physical variable detected by the sensor and the signals obtained from the sensor when this physical variable is detected by the sensor after preprocessing by the signal preprocessing unit.

The sensor, the signal preprocessing unit and the data processing unit are now coupled to one another, that is to say the circuit breaker is constructed, for example, in its final form. The at least one overall calibration value is then used by the data processing unit in order to associate a value of a physical variable on the basis of signals supplied to the data processing unit from the signal preprocessing unit.

The data processing unit therefore knows the physical variable and is able to carry out further steps, possibly as a function of the physical variable, be these calculation steps or the emission of control commands to further units of the circuit breaker.

The invention, in at least one embodiment, includes at least two novel aspects: On the one hand, the exact calibration values, which are normally measured with respect to the sensors, are then used. On the other hand, the circuit-breaker manufacturer no longer measures a calibration path which comprises a sensor and signal preprocessing unit together, but the signal preprocessing unit is calibrated individually. Since respective calibration values are available individually for the two subunits of the previous calibration path, that is to say the sensor and the signal preprocessing unit, high-precision values can be obtained. The sensor or else the signal preprocessing unit can be replaced at any time, when calibration values are provided for the new units.

One preferred application of the method according to at least one embodiment of the invention is for the sensor to be a current sensor, in which case the method can be carried out particularly easily, particularly in the case of Rogowski transducers, because these typically have a linear response, thus allowing a single calibration value (typically a proportionality factor) to be associated with the Rogowski transducers.

In principle, the method according to at least one embodiment of the invention can be carried out at one and the same location. However, it is also possible for the at least one first calibration value to be detected, as before, by the sensor manufacturer. The at least one first calibration value can be provided by the sensor manufacturer to his customer, by providing the first calibration value in written or printed form on a carrier. The simplest case is for the sensor itself to be the carrier, in which case the information relating to the first calibration value is then also scarcely lost. However, the information may, of course, also be provided on the packaging of the sensor, or an information sheet relating to the sensor.

In principle, a plurality of values which define a calibration curve can be provided as first calibration values, and this also applies to the second calibration values. The method can be carried out particularly easily if the first and the second calibration value each reflect a proportionality factor, because an overall calibration value can then be formed as a product, relating to them. However, an overall calibration value curve can also be formed as a product, when individual points on two calibration curves relating to the sensor and relating to the signal preprocessing unit are subjected to a multiplication process. However, in this case, it would then be necessary to take care to ensure that such points on the calibration curves are associated with one another, as a result of which it might be necessary to calculate intermediate values relating to one of the two calibration curves.

At least one embodiment of the invention results in a sensor: This is because the method according to at least one embodiment of the invention can be carried out particularly easily when a sensor manufacturer applies information about an exact calibration value relating to the detection of a physical variable, to the surface of the sensor. The calibration value can be indicated by a barcode or 2D code, or alternatively or in addition to this, as a numerical sequence, possibly with a checksum. The calibration value is intended to exactly describe a relationship between values of the physical variable detected by the sensor and signals which are emitted from the sensor when such values are present, for measurement accuracy purposes when a calibration has previously been carried out. In contrast to the situation until now, the sensor is therefore no longer coarsely associated with a specific tolerance class, but each sensor is an individual item with its own respectively associated calibration value.

At least one embodiment of the invention likewise relates to a circuit breaker having a sensor such as this, because the method according to at least one embodiment of the invention can be carried out particularly easily by the manufacturer of a circuit breaker such as this.

In particular, at least one embodiment of the invention also allows a sensor to be replaced without recalibration of the parts which have not been replaced. In this case the method according to at least one embodiment of the invention is carried out partially in advance during initial production of the circuit breaker and of its sensor, and completely, and individual steps are then carried out once again later. If the steps which are no longer carried out later from when the method was previously carried out completely are included, this once again results in the method according to at least one embodiment of the invention overall.

### BRIEF DESCRIPTION OF THE DRAWINGS

One example embodiment of the invention will be described in the following text with reference to the drawings, in which:

FIG. 1 shows, schematically, the arrangement of those components of a circuit breaker which are essential for description of an embodiment of the invention, and

FIG. 2 shows a step sequence according to an embodiment of the invention.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

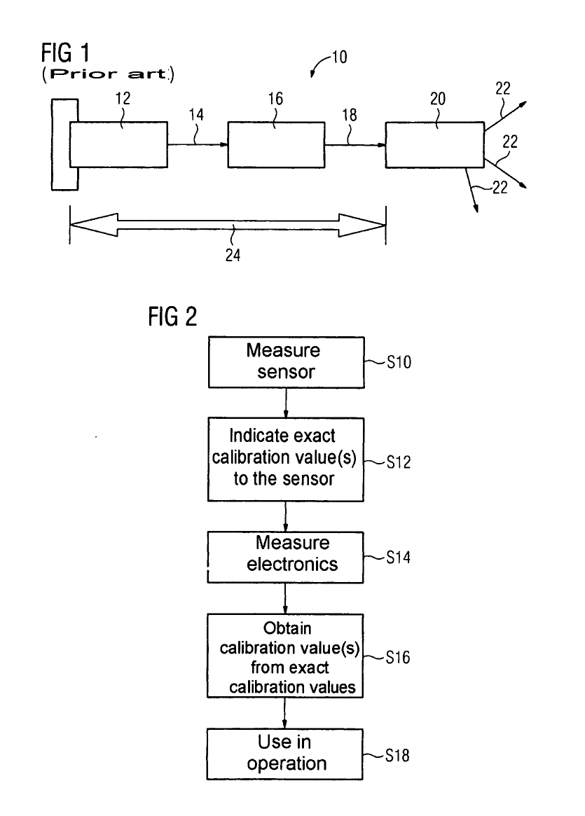

An arrangement which is annotated 10 in its entirety in FIG. 1 is part of a circuit breaker (not illustrated in the figures). A sensor 12 is used for detection of a physical variable, and emits signals to a signal preprocessing unit 16, as a function of the value of the physical variable, as indicated by the arrow 14. The sensor 12 is, for example, a Rogowski transducer which detects a current level. The signal preprocessing unit 16 preprocesses the signals from the transmitter 12 and emits the signals that have been preprocessed in this way to a data processing unit 20, as indicated by the arrow 18. This data preprocessing unit 20 evaluates the arriving signals and carries out further calculations or emits control commands to further units which are not shown from FIG. 1, as indicated by the arrows 22.

Fundamentally a calibration is required for measurements: The relationship between the actual values of a physical variable (actual values) and the emitted signals must be known. In the prior art, the entire arrangement comprising the sensor 12 and the signal preprocessing unit 16 is calibrated as indicated by the arrow 24: If the signal preprocessing unit is connected downstream from the sensor 12, specific values of the physical variable to be detected by the sensor 12 are set, and the signals emitted as indicated by the arrow 18 are detected at the same time. In precisely the same way, the physical variable can be measured with values being set by a second arrangement. The relationship can be described by an individual calibration value (for example a proportionality factor), possibly indicating a plurality of calibration values relating to different values of the physical variable, that is to say a calibration curve.

In contrast to the prior art, in the case of one embodiment of the method according to the invention, the step sequence indicated in FIG. 2 is carried out:

The sensor 12 is calibrated individually, that is to say is measured according to step S10: If the values of the physical variable are known, the signals emitted from the sensor 12 as indicated by the arrow 14 are detected. When the sensor is measured, an exact calibration value is determined (for example between the physical variable and the emitted signals), or else a plurality of such calibration values are determined. According to step S12, this exact calibration value or these exact calibration values is or are indicated to the sensor. The indication may, for example, be in the form of a bar code or 2D code on the sensor, which is read by a suitable reading unit. Equally well or additionally, the calibration value can be indicated via a numerical code or as an exact numerical value on the sensor 12, and the number is entered in the circuit breaker by an operator via a man-machine interface, as a result of which the data processing unit knows the exact calibration value.

The electronics are now measured, that is to say the signal preprocessing unit 16 (step S14). In the course of the calibration process that is carried out in this way, a calibration value is determined or a plurality of such calibration values are determined.

In step S16, an (overall) calibration value or a plurality of such calibration values is or are now determined from the calibration values relating to the sensor as determined in steps S10 and S14, on the one hand, and with respect to the signal preprocessing unit 16 on the other hand. If the calibration values relating to these units are in each case proportionality factors, the overall calibration value can be obtained easily in step S16 by multiplication of the two proportionality factors, thus obtaining a new proportionality factor.

The overall calibration value obtained in this way is then used by the processing unit during operation, according to step (S18): Thus when the sensor 12 detects the physical variable and emits signals that are dependent on its value, as indicated by the arrow 14, the signal preprocessing unit 16 receives these signals and, after preprocessing, emits the signals to the data processing unit 20 as indicated by the arrow 18, and the data processing unit 20 can deduce the value of the physical variable from the signals emitted as indicated by the arrow 18, to be precise actually using the calibration value, or the plurality of such calibration values, obtained in step S16.

The method according to an embodiment of the invention allows considerably more exact detection of values of the physical variable, because the two contribution elements, which are provided by the sensor 12 on the one hand and the signal preprocessing unit 16 on the other hand with respect to the signals arriving at the data processing unit 20 as indicated by the arrow 18, are detected in their own right.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combineable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for detection of a physical variable via a circuit breaker, the method comprising:
providing a sensor for emission of signals as a function of the physical variable;
providing a signal processing unit for reception of the signals from the sensor and for emission of signals which are obtained, by processing, from the received signals;
providing a data processing unit for reception of the signals emitted from the signal preprocessing unit;
detecting signals emitted from the sensor relating to values of the physical variable and determining at least one first calibration value, relating the values and the signals;
detecting signals emitted from the signal processing unit, and determining at least one second calibration value relating the signals emitted from the sensor and the signals received from the sensor and then processed in and emitted from the processing unit;
determining at least one overall calibration value from the at least one first and at least one second calibration values, the determined overall calibration value relating values of the physical variable detected by the sensor and the signals emitted from the sensor, and then received and processed by the signal preprocessing unit;
coupling the sensor, the signal processing unit and the data processing unit to one another; and
using the at least one overall calibration value, in a data processing unit, for association of a value of the physical variable with signals which are supplied to the data processing unit from the signal processing unit.

2. The method as claimed in claim 1, wherein the sensor is a current sensor.

3. The method as claimed in claim 2, wherein the current sensor is a Rogowski transducer, with which a single calibration value is associated.

4. The method as claimed in claim 1, wherein the at least one calibration value is provided in written or printed form on a carrier.

5. The method as claimed in claim 1, wherein the at least one overall calibration value is calculated as the product of a first and a second calibration value.

6. A sensor for detection of a physical variable having information, which is applied to its surface, about a calibration value, which exactly describes a relationship between values of the physical variable and signals which are emitted from the sensor when such values are present, for measurement accuracy purposes when a calibration is being carried out.

7. A circuit breaker comprising the sensor as claimed in claim 6.

8. The method as claimed in claim 4, wherein the sensor is the carrier.

9. The method as claimed in claim 1, wherein the overall calibration value includes a plurality of overall calibration values, and wherein each of the plurality of overall calibration values are calculated as the product of a first and a second calibration value.

10. A method for detection of a physical variable via a circuit breaker, the method comprising:
detecting signals emitted from a sensor, relating to values of the physical variable;
determining at least one first calibration value indicative of a relationship between the values and the detected signals;
detecting signals emitted from a signal processing unit;
determining at least one second calibration value indicative of a relationship between signals emitted from the sensor, and the signals received from the sensor, processed by the signal processing unit and then emitted from the signal processing unit;
determining at least one overall calibration value from the determined at least one first and at least one second calibration values, the determined overall calibration value being indicative of a relationship between values of the physical variable and the signals emitted from the sensor, and then processed by the signal processing unit; and
using the at least one overall calibration value, in a data processing unit, for association of a value of the physical variable with signals emitted from the signal processing unit to the data processing unit.

11. The method as claimed in claim 10, wherein the sensor is a current sensor.

12. The method as claimed in claim 11, wherein the current sensor is a Rogowski transducer, with which a single calibration value is associated.

13. The method as claimed in claim 10, wherein the at least one calibration value is provided in written or printed form on a carrier.

14. The method as claimed in claim 10, wherein the at least one overall calibration value is calculated as the product of a first and a second calibration value.

15. The method as claimed in claim 13, wherein the sensor is the carrier.
